(19) United States
(12) Patent Application Publication
(10) Pub. No.: US 2024/0153895 A1
(43) Pub. Date: May 9, 2024

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Harry-HakLay CHUANG, Zhubei City (TW); Wei-Cheng WU, Zhubei City (TW); Chung-Jen HUANG, Tainan City (TW); Yung Chun TU, Kaohsiung City (TW); Chien Lin LIU, Kaohsiung City (TW); Shun-Kuan LIN, Tainan City (TW); Ping-tzu CHEN, Tainan City (TW)

(21) Appl. No.: 18/303,137

(22) Filed: Apr. 19, 2023

Related U.S. Application Data
(60) Provisional application No. 63/382,937, filed on Nov. 9, 2022.

(51) Int. Cl. H01L 23/00

(52) U.S. Cl. CPC H01L 24/05; H01L 24/03; H01L 24/08; H01L 2224/0311; H01L 2224/03462; H01L 2224/0384; H01L 2224/05556; H01L 2224/05647; H01L 2224/08145

(57) ABSTRACT

Semiconductor dies of a semiconductor die package are directly bonded, and a top metal region may be formed over the semiconductor dies. A plurality of conductive terminals may be formed over the top metal region. The conductive terminals are formed of copper (Cu) or another material that enables low-temperature deposition process techniques, such as electroplating, to be used to form the conductive terminal. In this way, the conductive terminals of the semiconductor die packages described herein may be formed at a relatively low temperature. This reduces the likelihood of thermal deformation of semiconductor dies in the semiconductor die packages. The reduced thermal deformation reduces the likelihood of warpage, breakage, and/or other types of damage to the semiconductor dies of the semiconductor die packages, which may increase performance and/or increase yield of semiconductor die packages.

### CROSS-REFERENCE TO RELATED APPLICATION

This patent application claims priority to U.S. Provisional Patent Application No. 63/382,937, filed on Nov. 9, 2022, and entitled “SEMICONDUCTOR DIE PACKAGES AND METHODS OF FORMATION.” The disclosure of the prior application is considered part of and is incorporated by reference into this patent application.

### BACKGROUND

Various semiconductor device packing techniques may be used to incorporate one or more semiconductor dies into a semiconductor device package. In some cases, semiconductor dies may be stacked in a semiconductor device package to achieve a smaller horizontal or lateral footprint of the semiconductor device package and/or to increase the density of the semiconductor device package. Semiconductor device packing techniques that may be performed to integrate a plurality of semiconductor dies in a semiconductor device package may include integrated fanout (InFO), package on package (PoP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example implementation of a semiconductor die package described herein.

FIG. 3 illustrates another example implementation of the semiconductor die package described herein.

FIG. 4 is a diagram of an example implementation of a conductive terminal described herein.

FIG. 5 is a diagram of an example implementation of warpage in a semiconductor die package described herein.

FIGS. 6A-6E are diagrams of an example implementation of forming a semiconductor die described herein.

FIGS. 7A-7E are diagrams of an example implementation of forming a portion of a semiconductor die package described herein.

FIGS. 8A-8H are diagrams of an example implementation of forming a portion of a semiconductor die package described herein.

FIG. 9 is a diagram of example components of a device described herein.

FIG. 10 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a direct bonded semiconductor die package, a wafer on wafer (WoW) semiconductor die package, a chip on wafer (CoW) semiconductor die package, a die to die direct bonded semiconductor die package, semiconductor dies are directly bonded such that the semiconductor dies are vertically arranged in the semiconductor die package. The use of direct bonding and vertical stacking of dies may reduce interconnect lengths between the semiconductor dies (which reduces power loss and signal propagation times) and may enable increased density of semiconductor die packages in a semiconductor device package that includes the semiconductor die package.

After the semiconductor dies of the semiconductor die package are directly bonded, a top metal region may be formed over the semiconductor dies. A plurality of conductive terminals may be formed over the top metal region. The conductive terminals may enable the semiconductor die package to be mounted to a circuit board, a socket (e.g., a land grid array (LGA) socket), an interposer or redistribution structure of a semiconductor device package (e.g., a chip on wafer on substrate CoWoS package, an integrated fanout (InFO) package), and/or another type of mounting structure.

During formation of the conductive terminals, the semiconductor die package may be secured on a chuck in a processing chamber of a deposition tool. The chuck (e.g., an electrostatic chuck) may secure the semiconductor die package by applying a chuck voltage to the semiconductor die package. The chuck voltage is a type of bias voltage that is applied to the semiconductor die package to cause the semiconductor die package to be electrostatically attracted to the chuck.

In some cases, deposition of the conductive terminals involves increasing the temperature inside the processing chamber to an elevated temperature (e.g., to approximately 150 degrees Celsius or greater) and depositing the material of the conductive terminals at the elevated temperature. However, the elevated temperature may cause thermal deformation of the semiconductor dies of the semiconductor die package. Thermal deformation may occur particularly where the semiconductor dies of the semiconductor die package include a large quantity of metallization layers, such as 20 metallization layers or greater. The thermal deformation may result in warpage of the semiconductor dies of the semiconductor die package, which can cause the semiconductor dies of the semiconductor die package to fail and/or to be scrapped. To counteract the thermal deformation, an increased chuck voltage may be applied to the semiconductor die package. However, this can result in other issues, such as wafer breakage and other types of damage to the semiconductor die package.

In some implementations described herein, semiconductor dies of a semiconductor die package are directly bonded, and a top metal region may be formed over the semiconductor dies. A plurality of conductive terminals may be formed over the top metal region. The conductive terminals are formed of copper (Cu) or another material that enables low-temperature deposition process techniques, such as electroplating, to be used to form the conductive terminal. In this way, the conductive terminals of the semiconductor die packages described herein may be formed at a relatively low temperature, such as below approximately 150 degrees Celsius and/or at or near room temperature. This reduces the likelihood of thermal deformation of semiconductor dies in the semiconductor die packages. The reduced thermal deformation reduces the likelihood of warpage, breakage, and/or other types of damage to the semiconductor dies of the semiconductor die packages, which may increase performance and/or increase yield of semiconductor die packages.

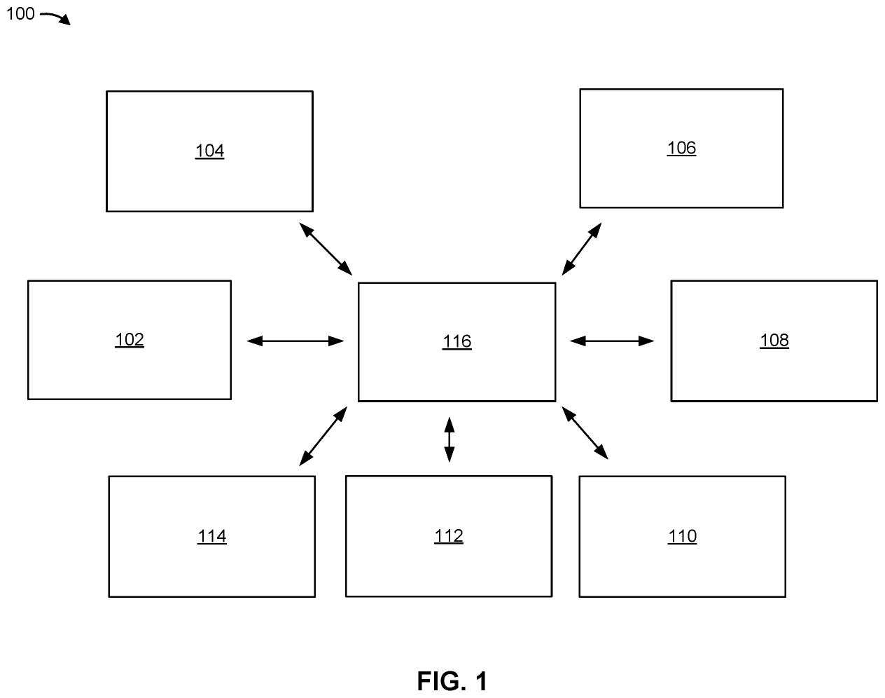

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may include a hybrid bonding tool. A hybrid bonding tool is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

In some implementations, one or more of the semiconductor processing tools 102-116 and/or the wafer/die transport tool 116 may perform one or more semiconductor processing operations described herein. For example, one or more of the semiconductor processing tools 102-114 and/or the wafer/die transport tool 116 may form one or more first dielectric layers over a first semiconductor die and a second semiconductor die that is bonded with the first semiconductor die; may form a recess through at least a subset of the one or more first dielectric layers; may form one or more second dielectric layers over the one or more first dielectric layers; may etch the one or more first dielectric layers and the one or more second dielectric layers to expand the recess to form a dual damascene recess; and/or may deposit conductive material in the dual damascene recess at approximately room temperature to form a conductive terminal in the dual damascene recess.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

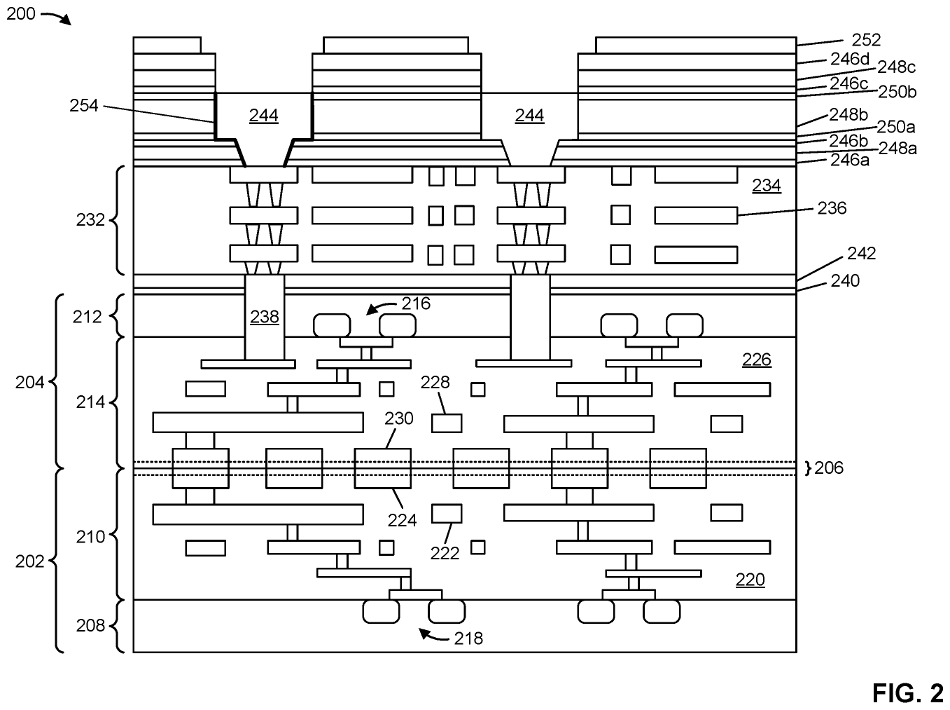

FIG. 2 is a diagram of an example implementation of a semiconductor die package 200 described herein. The semiconductor die package 200 is a semiconductor structure that includes an example of a wafer on wafer (WoW) semiconductor die package or another type of semiconductor die package in which semiconductor dies are directly bonded and vertically arranged or stacked.

As shown in the example implementation of the semiconductor die package 200 in FIG. 2, the semiconductor die package 200 includes a semiconductor die 202 and a semiconductor die 204. In some implementations, the semiconductor die package 200 includes additional semiconductor dies. The semiconductor die 202 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 202 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 204 may include the same type of semiconductor die as the semiconductor die 202, or may include a different type of semiconductor die.

The semiconductor die 202 and the semiconductor die 204 may be bonded together (e.g., directly bonded) at a bonding interface 206. In some implementations, one or more layers may be included between the semiconductor die 202 and the semiconductor die 204 at the bonding interface 206, such as one or more passivation layers, one or more bonding films, and/or one or more layers of another type. In some implementations, a thickness of the semiconductor die 204 is included in a range of approximately 0.5 microns to approximately 5 microns. However, other values for the range are within the scope of the present disclosure.

The semiconductor die 202 may include a device region 208 and an interconnect region 210 adjacent to and/or above the device region 208. In some implementations, the semiconductor die 202 may include additional regions. Similarly, the semiconductor die 204 may include a device region 212 and an interconnect region 214 adjacent to and/or below the device region 212. In some implementations, the semiconductor die 204 may include additional regions. The semiconductor die 202 and the semiconductor die 204 may be bonded at the interconnect region 210 and the interconnect region 214. The bonding interface 206 may be located at a first side of the interconnect region 214 facing the interconnect region 210 and corresponding to a first side of the semiconductor die 204.

The device regions 208 and 212 may each include a silicon (Si) substrate, a substrate formed of a material including silicon, a III-V compound semiconductor material substrate such as gallium arsenide (GaAs), a silicon on insulator (all) substrate, a germanium substrate (Ge), a silicon germanium (SiGe) substrate, a silicon carbide (SiC) substrate, or another type of semiconductor substrate. The device region 212 may include one or more semiconductor devices 216 included in the silicon substrate of the device region 212. The device region 208 may include one or more semiconductor devices 218 included in the silicon substrate of the device region 208. The semiconductor devices 216 and 218 may each include one or more transistors (e.g., planar transistors, fin field effect transistors (FinFETs), nanosheet transistors (e.g., gate all around (GAA) transistors), memory cells, capacitors, inductors, resistors, pixel sensors, and/or another type of semiconductor devices.

The interconnect regions 210 and 214 may be referred to as back end of line (BEOL) regions. The interconnect region 210 may include one or more dielectric layers 220, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 220. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 210 may further include metallization layers 222 in the one or more dielectric layers 220. The semiconductor devices 218 in the device region 208 may be electrically connected and/or physically connected with one or more of the metallization layers 222. The metallization layers 222 may include conductive lines, trenches, vias, pillars, interconnects, and/or another type of metallization layers. Contacts 224 may be included in the one or more dielectric layers 220 of the interconnect region 210. The contacts 224 may be electrically connected and/or physically connected with one or more of the metallization layers 222. The contacts 224 may include conductive terminals, conductive pads, conductive pillars, and/or another type of contacts. The metallization layers 222 and the contacts 224 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 214 may include one or more dielectric layers 226, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the one or more dielectric layers 226. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 214 may further include metallization layers 228 in the one or more dielectric layers 226. The semiconductor devices 216 in the device region 212 may be electrically connected and/or physically connected with one or more of the metallization layers 228. The metallization layers 228 may include conductive lines, trenches, vias, pillars, interconnects, and/or another type of metallization layers. Contacts 230 may be included in the one or more dielectric layers 226 of the interconnect region 214. The contacts 230 may be electrically connected and/or physically connected with one or more of the metallization layers 228. Moreover, the contacts 230 may be electrically and/or physically connected with the contacts 224 of the semiconductor die 202. The contacts 230 may include conductive terminals, conductive pads, conductive pillars, under bump metallization (UBM) structures, and/or another type of contacts. The metallization layers 228 and the contacts 230 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2, the semiconductor die package 200 may include a top metal region 232. The top metal region 232 may include a redistribution layer (RDL) structure and/or another type of redistribution structure. The top metal region 232 may be configured to fan out and/or route signals and I/O of the semiconductor dies 202 and 204.

The top metal region 232 may include one or more dielectric layers 234 and a plurality of metallization layers 236 disposed in the one or more dielectric layers 234. The dielectric layer(s) 234 may include a silicon nitride (SiNₓ), an oxide (e.g., a silicon oxide (SiOₓ) and/or another oxide material), a low dielectric constant (low-k) dielectric material, and/or another suitable dielectric material.

The metallization layers 236 of the top metal region 232 may include one or more materials such as a gold (Au) material, a copper (Cu) material, a silver (Ag) material, a nickel (Ni) material, a tin (Sn) material, and/or a palladium (Pd) material, among other examples. The metallization layers 236 of the top metal region 232 may include metal lines, vias, interconnects, and/or another type of metallization layers.

As further shown in FIG. 2, the semiconductor die package 200 may include one or more backside through silicon via (BTSV) structures 238 through the device region 212, and into a portion of the interconnect region 214. The one or more BTSV structures 238 may include vertically elongated conductive structures (e.g., conductive pillars, conductive vias) that electrically connect one or more of the metallization layers 228 in the interconnect region 214 of the semiconductor die 204 to one or more metallization layers 236 in the top metal region 232. The BTSV structures 238 may be referred to as through silicon via (TSV) structures in that the BTSV structures 238 extend fully through a silicon substrate (e.g., the silicon substrate of the device region 212) as opposed to extending fully through a dielectric layer or an insulator layer. The one or more BTSV structures 238 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

A buffer oxide layer 240 may be included between the semiconductor die 204 and the top metal region 232. In particular, the buffer oxide layer 240 may be included over and/or on the second side of the semiconductor die 204. The one or more BTSV structures 238 may extend through the buffer oxide layer 240. The buffer oxide layer 240 may include one or more oxide layers that function as a buffer between the device region 212 of the semiconductor die 204 and the top metal region 232. The buffer oxide layer 240 may include one or more oxide materials, such as a silicon oxide (SiOₓ), a silicon oxycarbide (SiOC), a silicon oxynitride (SiON), and/or another type of oxide material.

A high-k dielectric layer 242 may be included between the semiconductor die 204 and the top metal region 232. In particular, the high-k dielectric layer 242 may be included over the second side of the semiconductor die 204 and on the buffer oxide layer 240. The one or more BTSV structures 238 may extend through the high-k dielectric layer 242. The high-k dielectric layer 242 may include one or more high-k dielectric materials such as a hafnium oxide (HfOₓ), an aluminum oxide (AlₓO_{y}), a tantalum oxide (TaₓO_{y}), a gallium oxide (GaₓO_{y}), a titanium oxide (TiOₓ), a niobium oxide (NbₓO_{y}), and/or another suitable high-k dielectric material, among other examples.

As further shown in FIG. 2, the semiconductor die package 200 may include conductive terminals 244. The conductive terminals 244 may be electrically connected and/or physically connected with one or more metallization layers 236 in the top metal region 232. The conductive terminals 244 may include copper pads and/or another type of conductive structures that enable the semiconductor die package 200 to be mounted to a circuit board, a socket (e.g., a land grid array (LGA) socket), an interposer or redistribution structure of a semiconductor device package (e.g., a chip on wafer on substrate CoWoS package, an integrated fanout (InFO) package), and/or another type of mounting structure.

The conductive terminals 244 may include one or more conductive materials. In particular, the conductive terminals 244 may include copper (Cu), a copper-containing material, and/or another suitable material that can be deposited at relatively low temperatures (e.g., below approximately 150 degrees Celsius and/or approximately at room temperature) to reduce the likelihood of thermal deformation and warpage of the semiconductor dies 202 and 204 during manufacturing of the semiconductor die package 200. A conductive terminal 244 may include an approximately flat top surface that extends from one edge or side of the conductive terminal 244 to an opposing edge or side of the conductive terminal 244. In some implementations, the conductive terminals 244 include primarily copper (e.g., >50% concentration of copper). In some implementations, the conductive terminals 224 include “pure” copper (e.g., approximately 99% oxygen-free copper).

As further shown in FIG. 2, one or more dielectric layers may be included over the semiconductor die 202 and over the semiconductor die 204 that is bonded with the semiconductor die 202. A dielectric layer 246a may be included over and/or on the top metal region 232 that is over the semiconductor dies 202 and 204. A dielectric layer 248a may be included over and/or on the dielectric layer 246a. A dielectric layer 246b may be included over and/or on the dielectric layer 248a. A dielectric layer 250a may be formed over and/or on the dielectric layer 246b. A dielectric layer 248b may be included over and/or on the dielectric layer 250a. A dielectric layer 250b may be included over and/or on the dielectric layer 248b. A dielectric layer 246c may be included over and/or on the dielectric layer 250b. A dielectric layer 248c may be included over and/or on the dielectric layer 246c. A dielectric layer 246d may be included over and/or on the dielectric layer 248c. In some implementations, a polymer layer 252 may be included over and/or on the dielectric layer 246d. Alternatively, the polymer layer 252 may be omitted from the semiconductor device.

The dielectric layers 246a-246d may each include a silicon nitride (SiₓN_{y} such as Si₃N₄) and/or another suitable dielectric material. The dielectric layers 248a-248c may each include a silicon oxide (SiOₓ such as SiO₂), an undoped silicate glass (USG), and/or another suitable dielectric material. The dielectric layers 250a and 250b may each include silicon oxynitride (SiON) and/or another suitable dielectric material. The polymer layer 252 may include polybenzoxazole (PBO), a polyimide, a low temperature polyimide (LTPI), an epoxy resin, an acrylic reason, a phenol resin, benzocyclobutene (BCB), one or more dielectric layers, one or more dielectric layers, and/or another suitable polymer material.

The one or more conductive structures 244 may be included in one or more of the dielectric layers 246a, 246b, 246c, 246d, 248a, 248b, 248c, 250a, and/or 250b. In some implementations, one or more of the dielectric layers 246a, 246b, 246c, 246d, 248a, 248b, 248c, 250a, and/or 250b may be located above a top surface of the one or more conductive structures 244 such that the one or more conductive structures 244 are included in one or more recesses in the dielectric layers 246a, 246b, 246c, 246d, 248a, 248b, 248c, 250a, and/or 250b. In some implementations, a barrier layer 254 is included between the conductive structures 244 and the dielectric layers to prevent the copper atoms from diffusing into the dielectric layers. The barrier layer 254 may include a titanium (Ti) layer, a titanium nitride (TiN) layer, a tantalum (Ta) layer, a tantalum nitride (TaN) layer, or combinations thereof.

As indicated above, FIG. 2 is provided as an example. Other examples may differ from what is described with regard to FIG. 2.

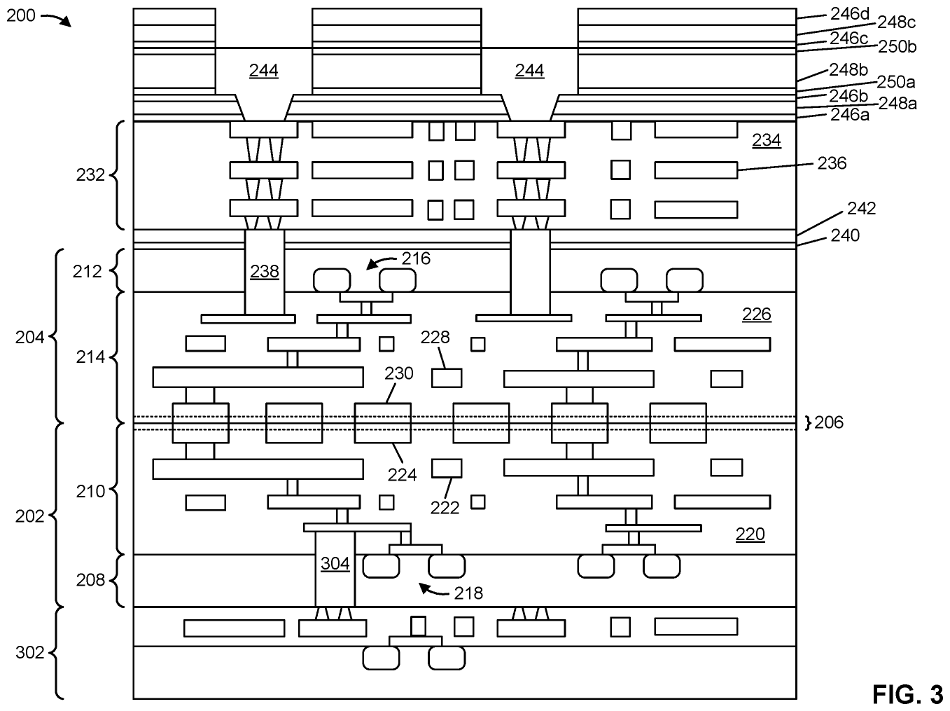

FIG. 3 illustrates another example implementation of the semiconductor die package 200 described herein. The example implementation of the semiconductor die package 200 illustrated in FIG. 3 is similar to the example implementation of the semiconductor die package 200 illustrated in FIG. 2. However, the example implementation of the semiconductor die package 200 illustrated FIG. 3 is a semiconductor structure that includes a triple-stacked semiconductor die package, in which the semiconductor die 202, the semiconductor die 204, and a semiconductor die 302 are directly bonded and vertically arranged. The semiconductor die 202 and the semiconductor die 204 are bonded at a first side of the semiconductor die 202. The semiconductor die 202 and the semiconductor die 302 are bonded at a second side of the semiconductor die 202 opposing the first side. The semiconductor die 302 may include a device region and an interconnect region, similar to the semiconductor die 202 and the semiconductor die 204. The semiconductor die 302 may be electrically connected with one or more metallization layers 222 in the interconnect region 210 of the semiconductor die 202 by one or more through silicon vias (TSVs) 304.

As indicated above, FIG. 3 is provided as an example. Other examples may differ from what is described with regard to FIG. 3.

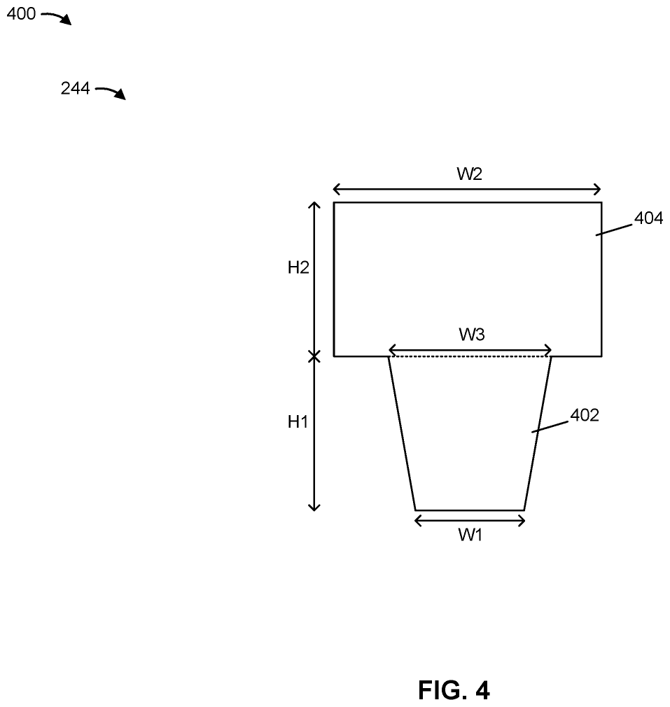

FIG. 4 is a diagram of an example implementation 400 of a conductive terminal 244 described herein. As described herein, the conductive terminal 244 may include a copper pad or a conductive structure that includes copper, which enables the conductive terminal 244 to be formed at a relatively low temperature (e.g., at approximately room temperature).

As shown in FIG. 4, the conductive terminal 244 may include a tapered portion 402 and an approximately straight-walled portion 404 over the tapered portion 402. The tapered portion 402 and the approximately straight-walled portion 404 may be a single continuous conductive structure that corresponds to the conductive terminal 244. The tapered portion 402 includes tapered sidewalls that taper from a top portion of the tapered portion 402 to a bottom surface of the tapered portion 402. The bottom surface of the tapered portion 402 may correspond to a bottom surface of the conductive terminal 244.

The approximately straight-walled portion 404 may have approximately parallel sidewalls. The top surface of the approximately straight-walled portion 404 may correspond to a top surface of the conductive terminal 244.

As further shown in FIG. 4, an example dimension of the conductive terminal 244 may include a height (H1) of the tapered portion 402. In some implementations, the height (H1) of the tapered portion 402 may be included in a range of approximately 0.228 microns to approximately 0.912 microns. However, other values for the range are within the scope of the present disclosure.

Another example dimension of the conductive terminal 244 may include a height (H2) of the approximately straight-walled portion 404. In some implementations, the height (H2) of the approximately straight-walled portion 404 may be included in a range of approximately 1.68 microns to approximately 3.92 microns. However, other values for the range are within the scope of the present disclosure.

The height (H2) of the approximately straight-walled portion 404 may be greater relative to the height (H1) of the tapered portion 402. In some implementations, a ratio of the height (H2) of the approximately straight-walled portion 404 to the height (H1) of the tapered portion 402 may be included in a range of approximately 1.8:1 to approximately 18:1 to reduce the amount of current leakage in the conductive terminal 244, to reduce the amount of resistance-capacitance (RC) delay in the conductive terminal 244, and to achieve a sufficiently low resistance for the conductive terminal 244, among other examples. However, other values for the range are within the scope of the present disclosure.

As further shown in FIG. 4, an example dimension of the conductive terminal 244 may include a width (W1) of the bottom surface of the tapered portion 402. The width (W1) of the bottom surface of the tapered portion 402 may correspond to the critical dimension (CD) or bottom width of the conductive terminal 244. In some implementations, the width (W1) of the bottom surface of the tapered portion 402 may be included in a range of approximately 0.0784 microns to approximately 0.3136 microns. However, other values for the range are within the scope of the present disclosure.

Another example dimension of the conductive terminal 244 may include a width (W2) of the top surface of the approximately straight-walled portion 404. The width (W2) of the top surface of the approximately straight-walled portion 404 may correspond to the width of the top surface of the conductive terminal 244. In some implementations, the width (W2) of the top surface of the approximately straight-walled portion 304 may be included in a range of approximately 14.972 microns to approximately 59.88 microns. However, other values for the range are within the scope of the present disclosure.

Another example dimension of the conductive terminal 244 may include a width (W3) of the top portion of the tapered portion 402. In some implementations, the width (W3) of the top portion of the tapered portion 402 may be included in a range of approximately 0.3432 microns to approximately 0.9152 microns. However, other values for the range are within the scope of the present disclosure.

In some implementations, a ratio of the height (H1) of the tapered portion 402 to the width (W3) of the top of the tapered portion 402 is included in a range of approximately 0.25:1 to approximately 2.7:1 to achieve a sufficiently low resistance for the conductive terminal 244 while reducing the likelihood of electrical shorting around the conductive terminal 244. However, other values for the range are within the scope of the present disclosure.

In some implementations, a ratio, of the width (W2) of the approximately straight-walled portion 404 to the height (H2) of the approximately straight-walled portion 404, is included in a range of approximately 3.8:1 to approximately 35.7:1 to achieve a sufficiently low resistance for the conductive terminal 244 while reducing the likelihood of electrical shorting around the conductive terminal 244. However, other values for the range are within the scope of the present disclosure.

In some implementations, the width (W2) of the approximately straight-walled portion 404 is greater relative to the widths (W1) and (W3) of the tapered portion 402. In some implementations, the height (H1) of the tapered portion 402 is greater relative to the width (W1) of a bottom surface of the tapered portion 402. In some implementations, the width (W3) of a top of the tapered portion 402 is greater relative to the width (W1) of the bottom surface of the tapered portion 402.

As indicated above, FIG. 4 is provided as an example. Other examples may differ from what is described with regard to FIG. 4.

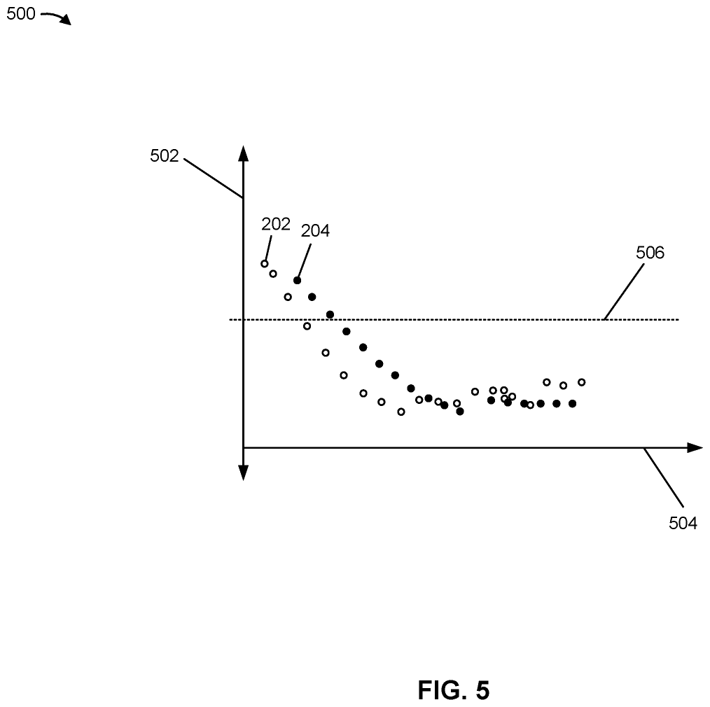

FIG. 5 is a diagram of an example implementation 500 of warpage in a semiconductor die package 200 described herein. The warpage for the semiconductor die 202 and for the semiconductor die 204 are illustrated as a function of warpage magnitude 502 and temperature 504 during a deposition operation to deposit the conductive terminals 244 of the semiconductor die package 200.

The direction of the warpage magnitude 502 is illustrated relative to a zero warpage center line 506. When the warpage of the semiconductor die 202 and the semiconductor die 204 is above the zero warpage center line 506, the semiconductor die 202 and the semiconductor die 204 are warped in a concave manner in which edges of the semiconductor die 202 and the semiconductor die 204 are curled upward. When the warpage of the semiconductor die 202 and the semiconductor die 204 is below the zero warpage center line 506, the semiconductor die 202 and the semiconductor die 204 are warped in a convex manner in which edges of the semiconductor die 202 and the semiconductor die 204 are curled downward.

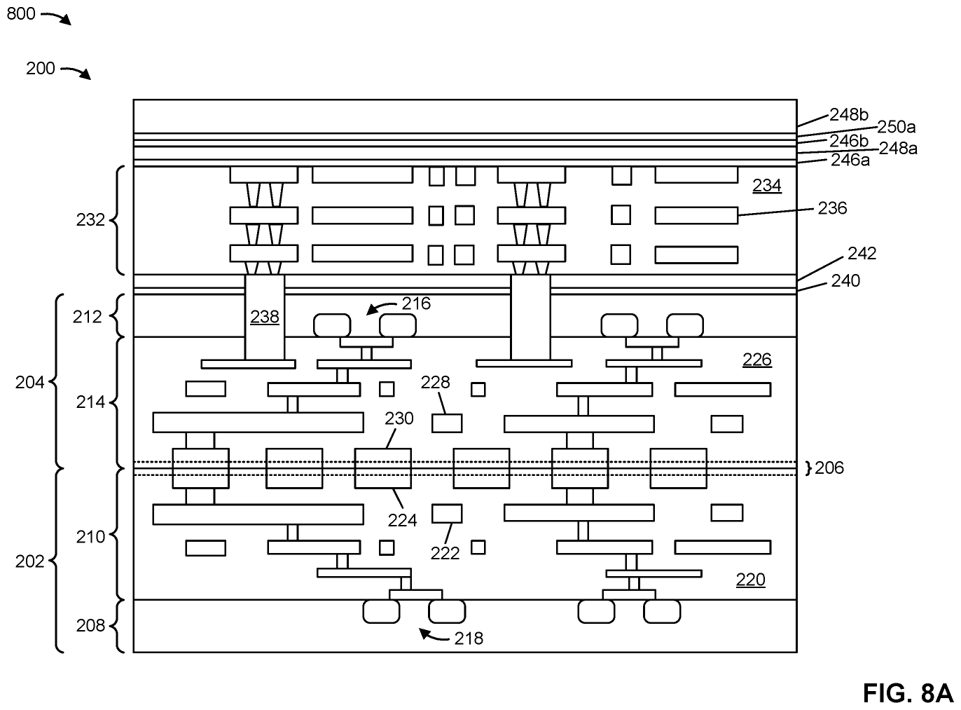

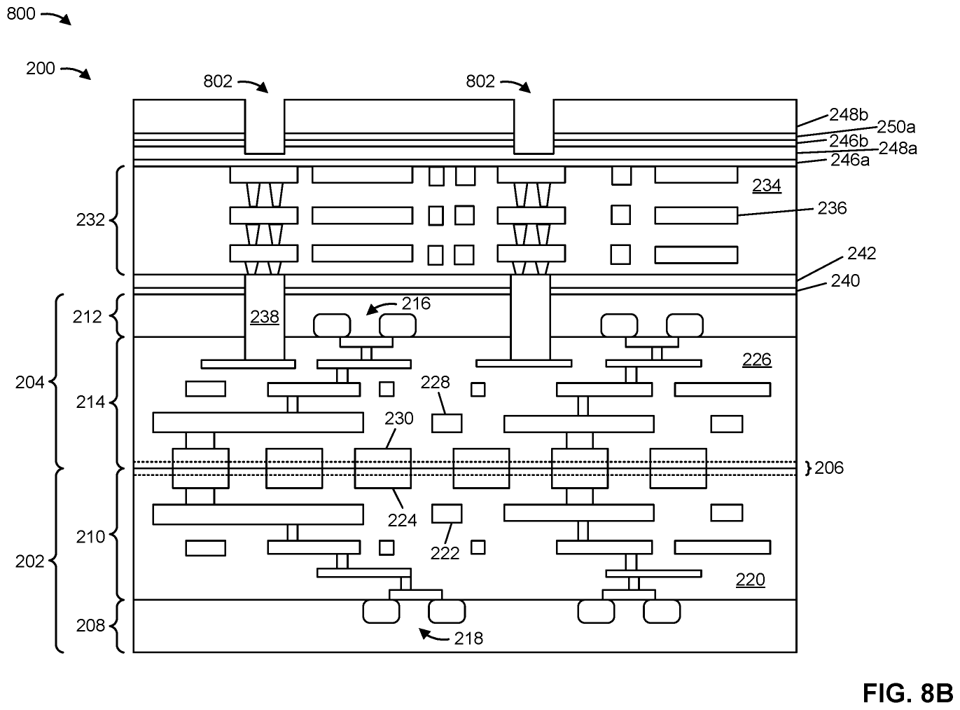

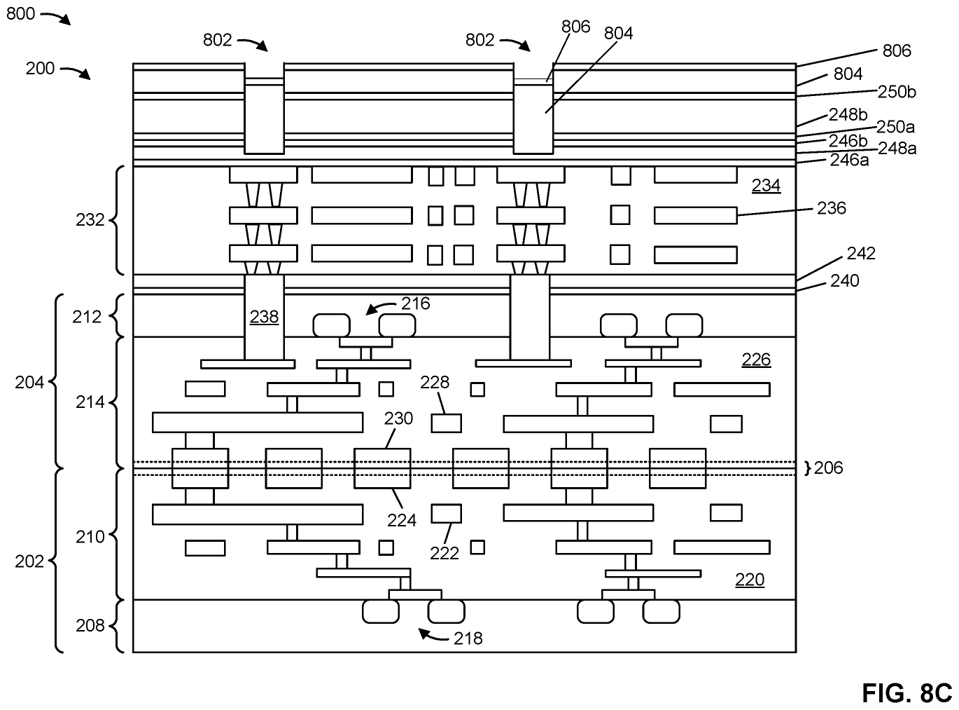

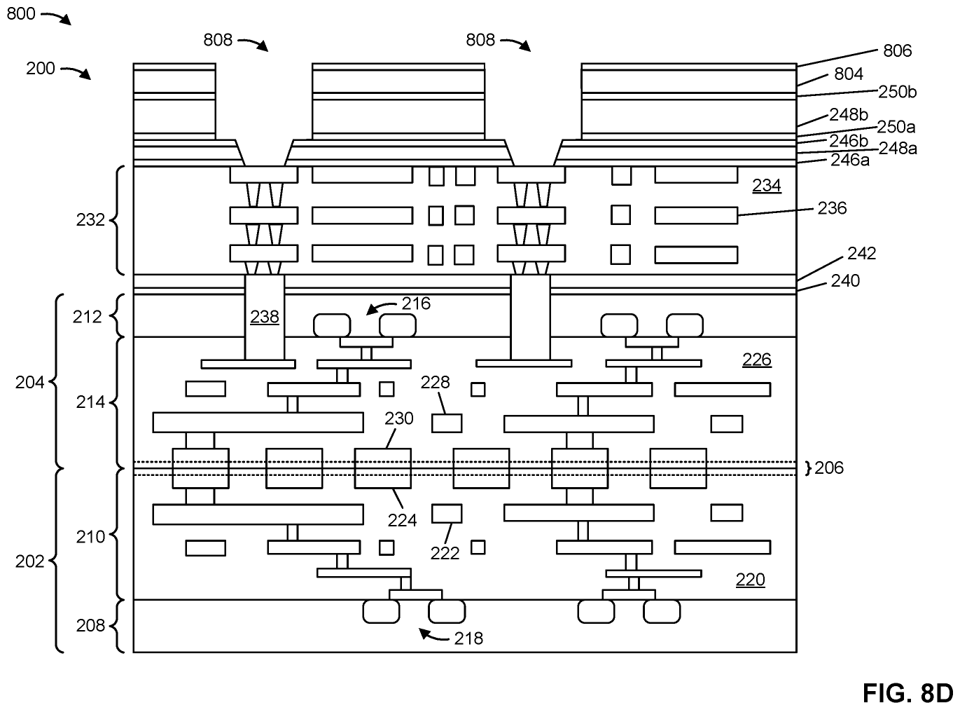

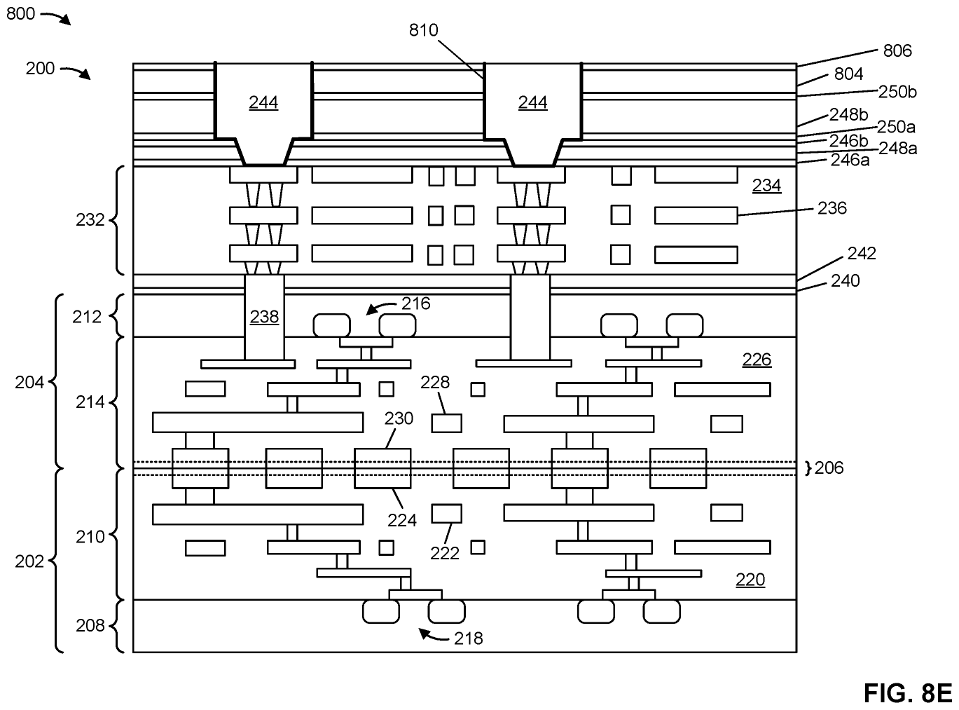

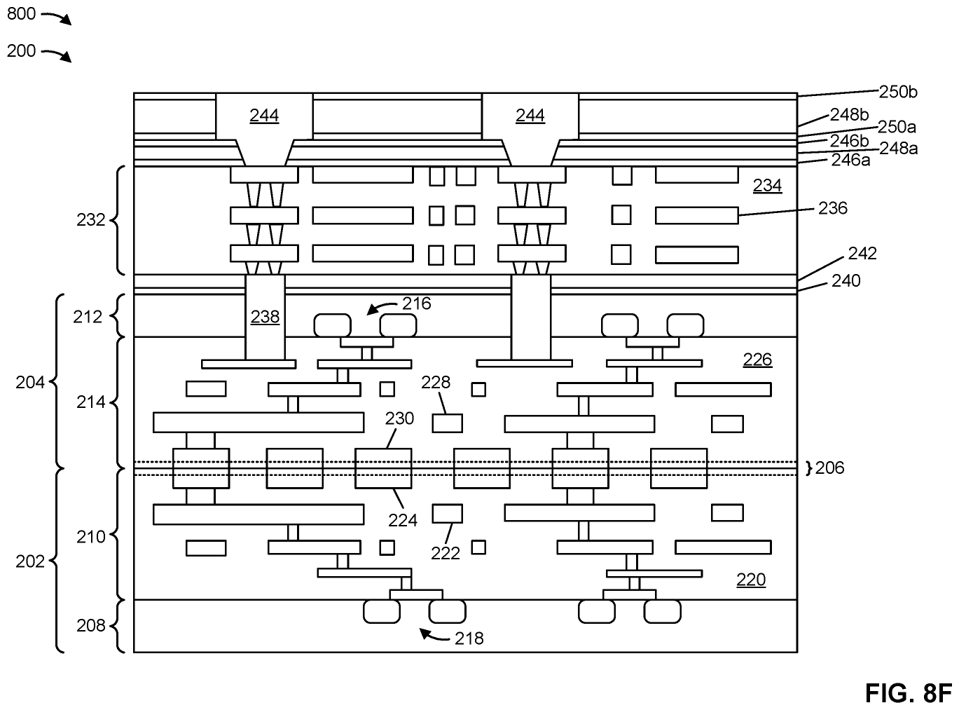

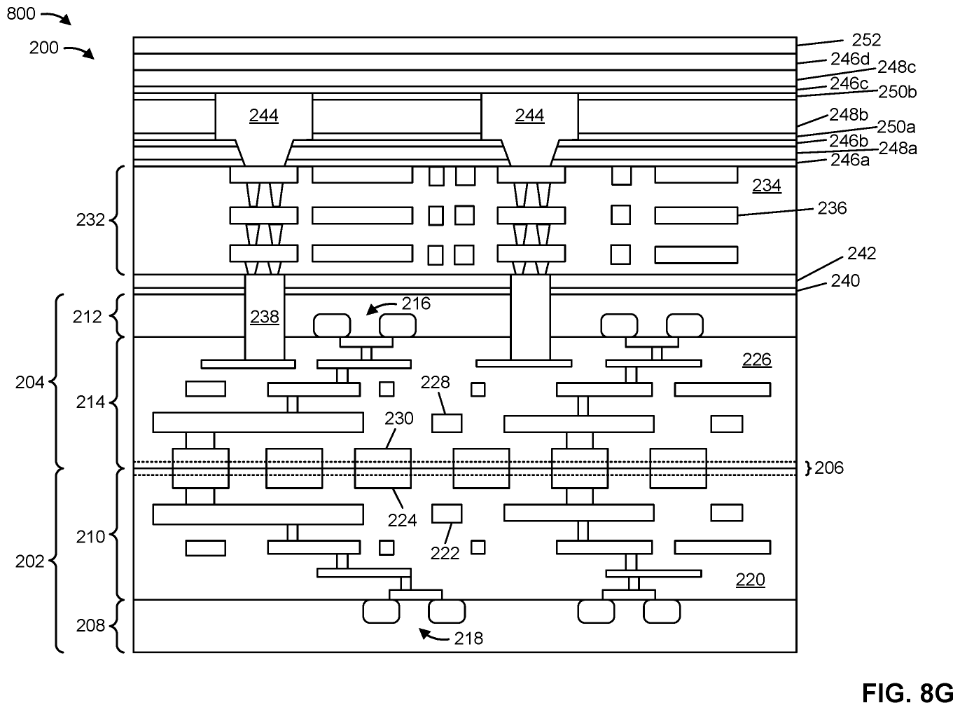

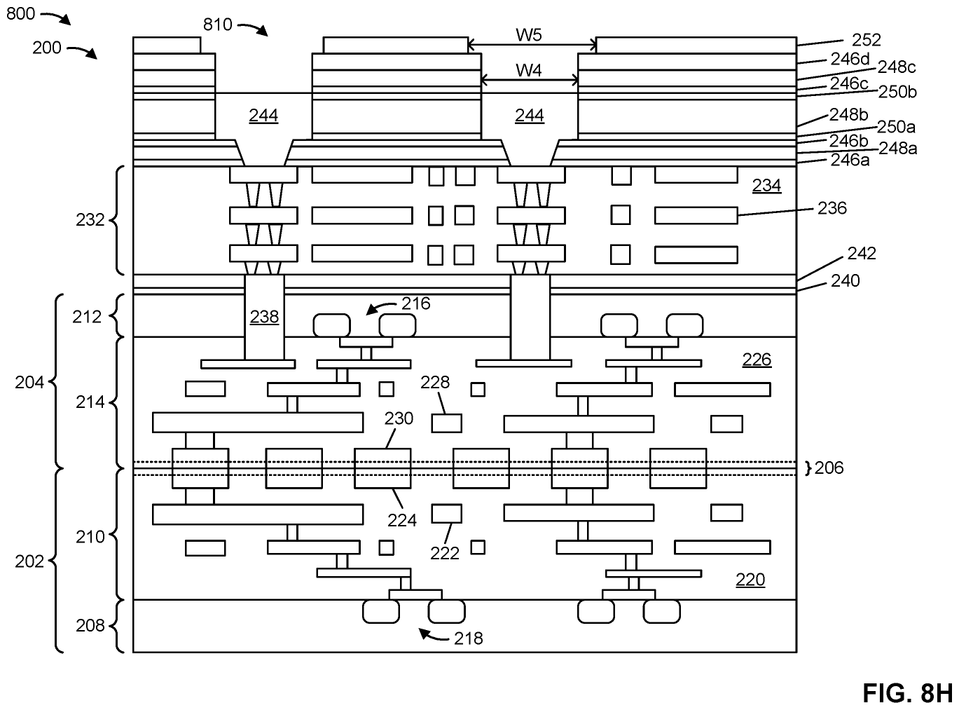

The warpage magnitude 502 of the semiconductor die 202 and the semiconductor die 204 may generally increase as the temperature 504 during the deposition operation to deposit the conductive terminals 244 increases. As described in connection with FIGS. 8A-8H and elsewhere herein, the conductive terminals 244 may be formed of a conductive material such as copper (Cu) or another type of conductive material that enables the conductive terminals 244 to be deposited using a deposition technique (e.g., electroplating) at a relatively low temperature (e.g., at or near room temperature). This reduces the likelihood of thermal deformation and warpage of the semiconductor die 202 and the semiconductor die 204 relative to forming the conductive terminals 244 of aluminum (Al) or another conductive material that is deposited at a relatively high temperature (e.g., approximately 150 degrees Celsius or greater) by CVD, PVD, or another high-temperature deposition technique.

As indicated above, FIG. 5 is provided as an example. Other examples may differ from what is described with regard to FIG. 5.

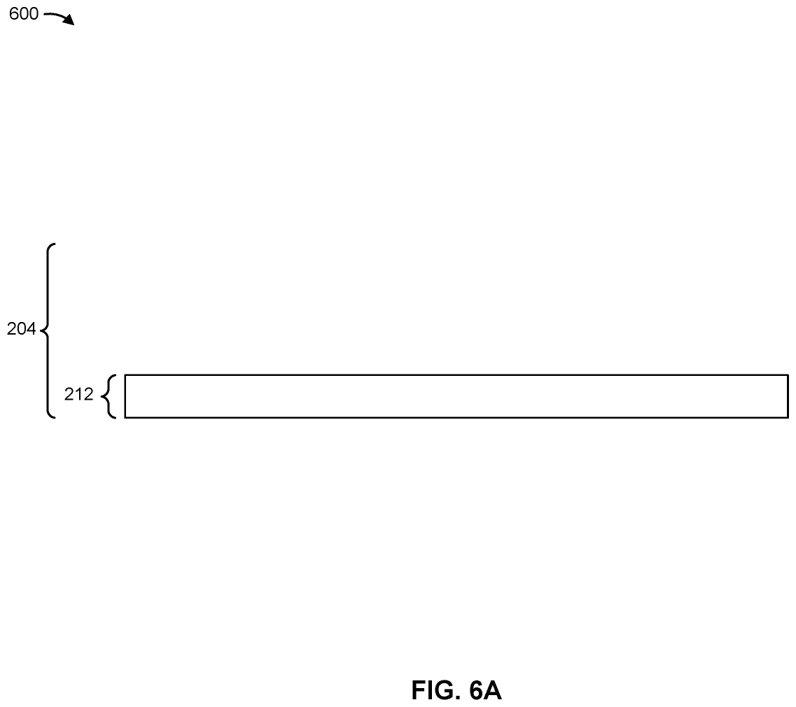

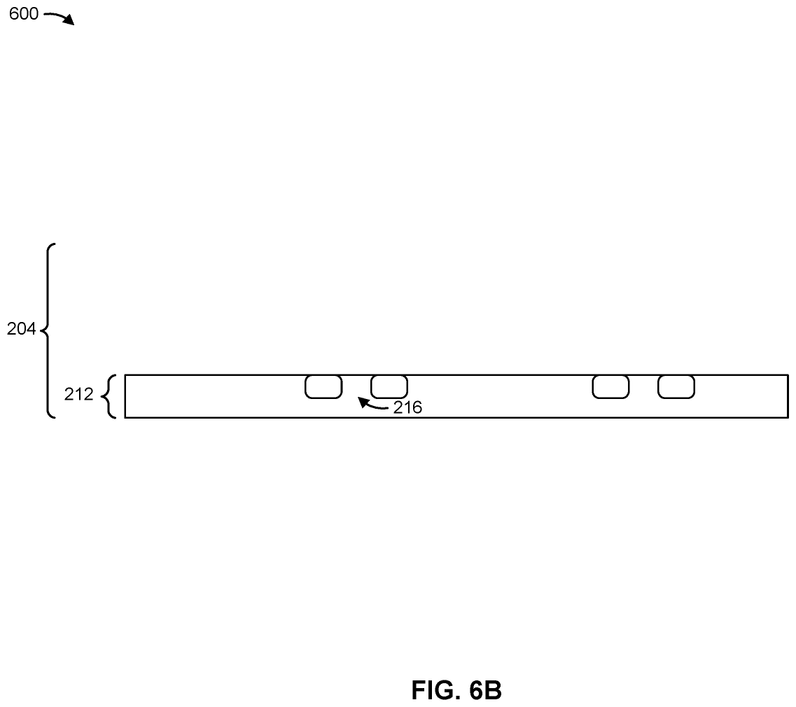

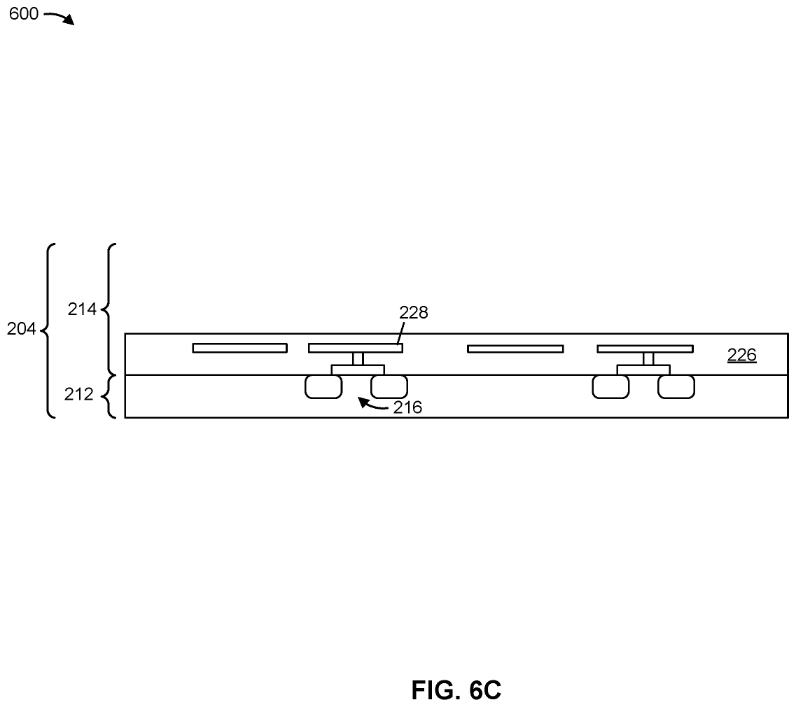

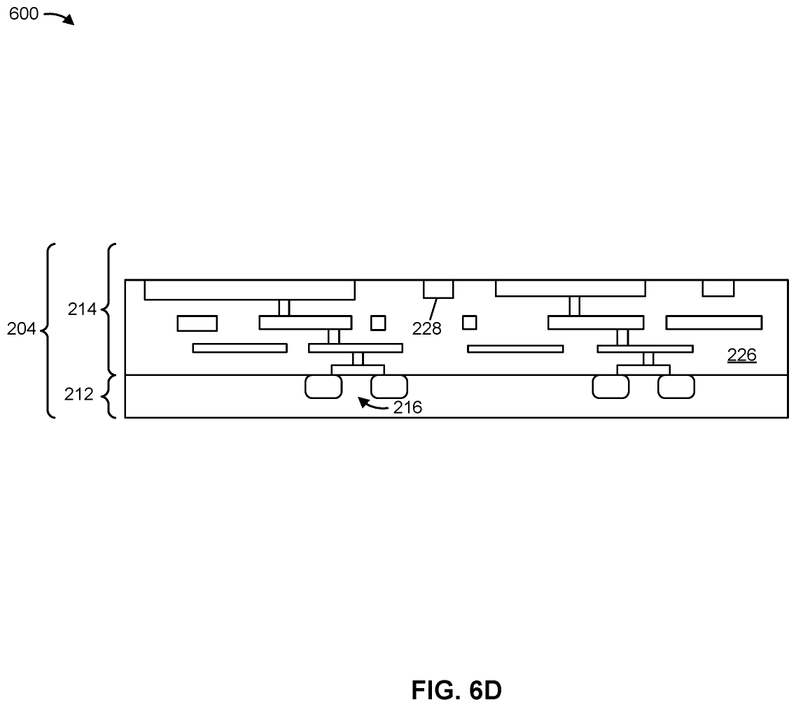

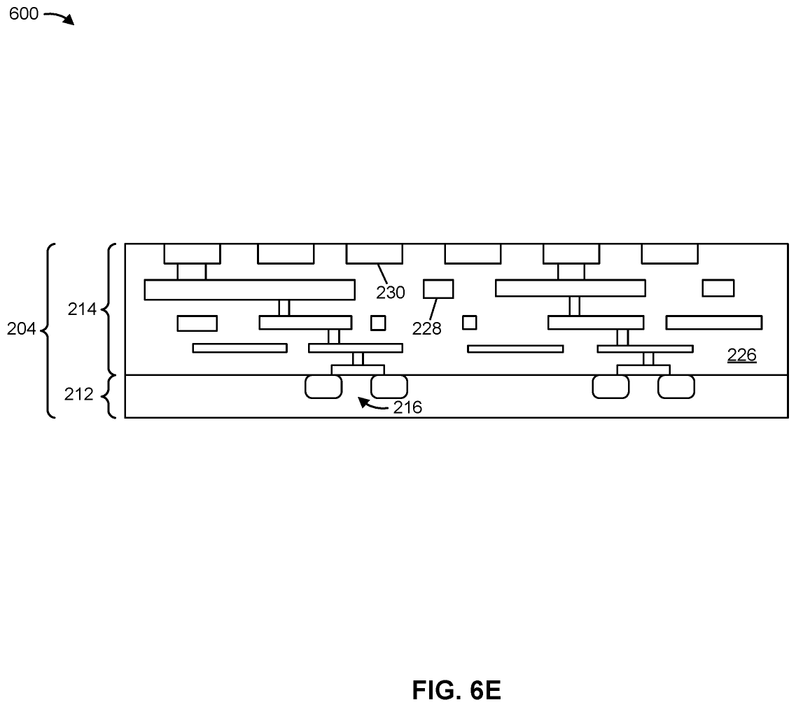

FIGS. 6A-6E are diagrams of an example implementation 600 of forming a semiconductor die described herein. In some implementations, the example implementation 600 includes an example process (or a portion thereof) for forming the semiconductor die 204. While the operations described in connection with FIGS. 6A-6E are described in connection with the semiconductor die 204, similar operations may be performed to form the semiconductor die 202.

In some implementations, one or more operations described in connection with FIGS. 6A-6E may be performed by one or more of the semiconductor processing tools 102-114 and/or the wafer/die transport tool 116. In some implementations, one or more operations described in connection with FIGS. 6A-6E may be performed by another semiconductor processing tool. Turning to FIG. 6A, one or more of the operations in the example implementation 600 may be performed in connection with the silicon substrate of the device region 212 of the semiconductor die 204.

As shown in FIG. 6B, one or more semiconductor devices 216 may be formed in the device region 212. For example, one or more of the semiconductor processing tools 102-114 may perform photolithography patterning operations, etching operations, deposition operations, CMP operations, and/or another type of operations to form one or more transistors, one or more capacitors, one or more memory cells, and/or one or more semiconductor devices of another type. In some implementations, one or more regions of the silicon substrate of the device region 212 may be doped in an ion implantation operation to form one or more p-wells, one or more n-wells, and/or one or more deep n-wells. In some implementations, the deposition tool 102 may deposit one or more source/drain regions, one or more source/drain regions, and/or one or more shallow trench isolation (STI) regions, among other examples.

As shown in FIGS. 6C-6E, the interconnect region 214 of the semiconductor die 204 may be formed over and/or on the silicon substrate of the device region 212. One or more of the semiconductor processing tools 102-114 may form the interconnect region 214 by forming one or more dielectric layers 226 and forming a plurality of metallization layers 228 in the plurality of dielectric layers 226. For example, the deposition tool 102 may deposit a first layer of the one or more dielectric layers 226 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 228 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 216. The deposition tool 102, the etch tool 108, the plating tool 112, and/or another semiconductor processing tool may continue to perform similar processing operations to forming the interconnect region 214 until a sufficient or desired arrangement of metallization layers 228 is achieved.

As shown in FIG. 6E, one or more of the semiconductor processing tools 102-114 may form another layer of the one or more dielectric layers 226, and may form a plurality of contacts 230 in the layer such that the contacts 230 are electrically connected and/or physically connected with one or more of the metallization layers 228. For example, the deposition tool 102 may deposit the layer of the one or more dielectric layers 226 (e.g., using a CVD technique, an ALD technique, a PVD technique, and/or another type of deposition technique), the etch tool 108 may remove portions of the layer to form recesses in the layer, and the deposition tool 102 and/or the plating tool 112 may form the contacts 230 in the recesses (e.g., using a CVD technique, an ALD technique, a PVD technique, an electroplating technique, and/or another type of deposition technique).

As indicated above, FIGS. 6A-6E are provided as an example. Other examples may differ from what is described with regard to FIGS. 6A-6E.

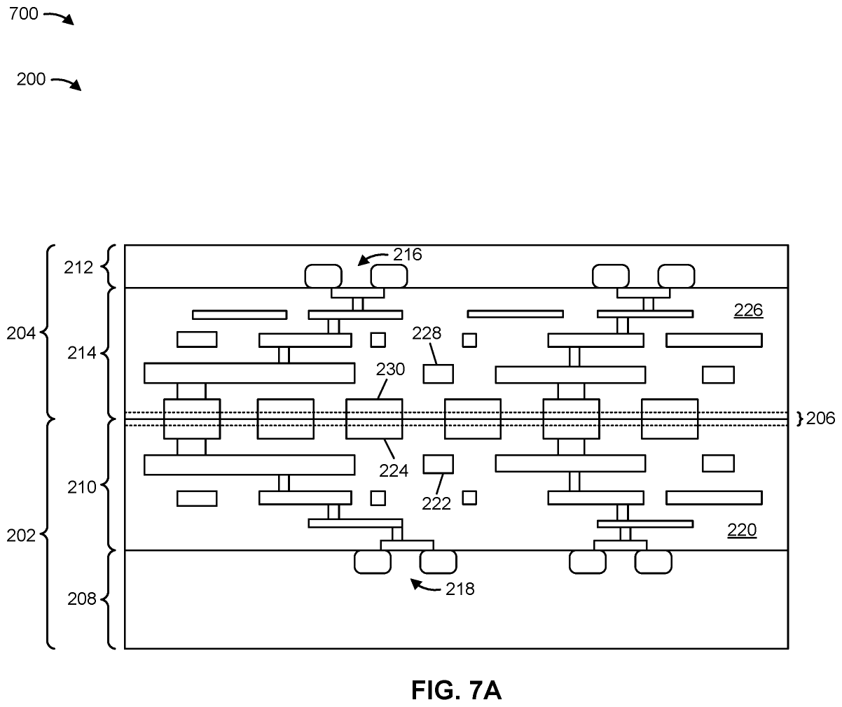

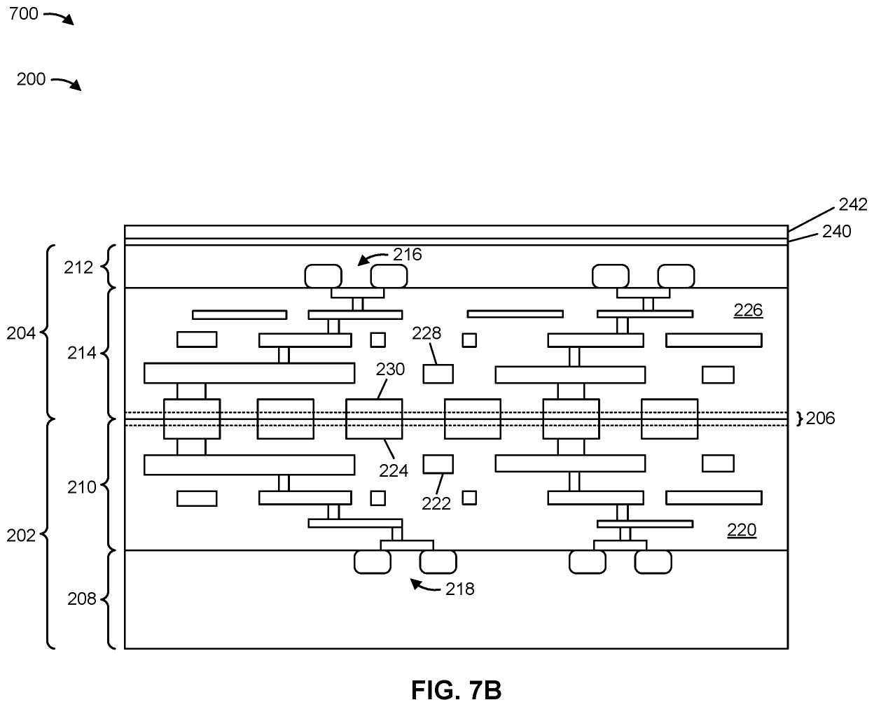

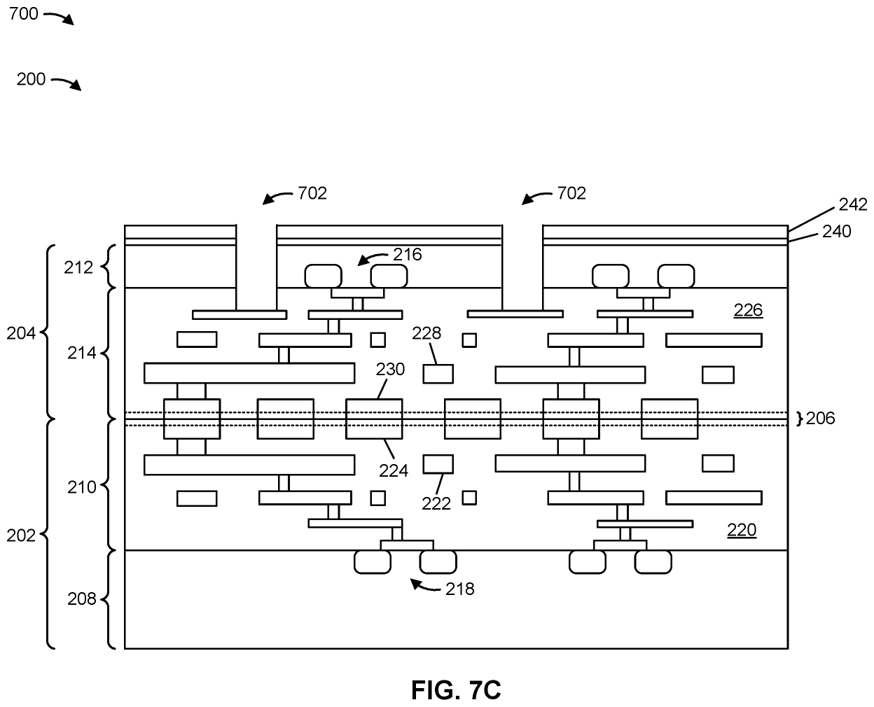

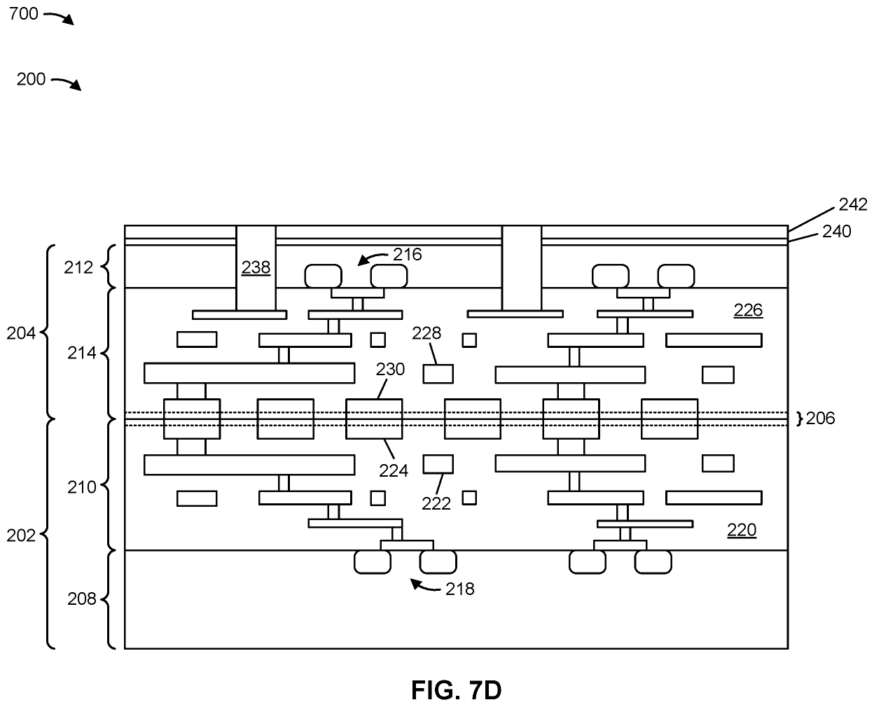

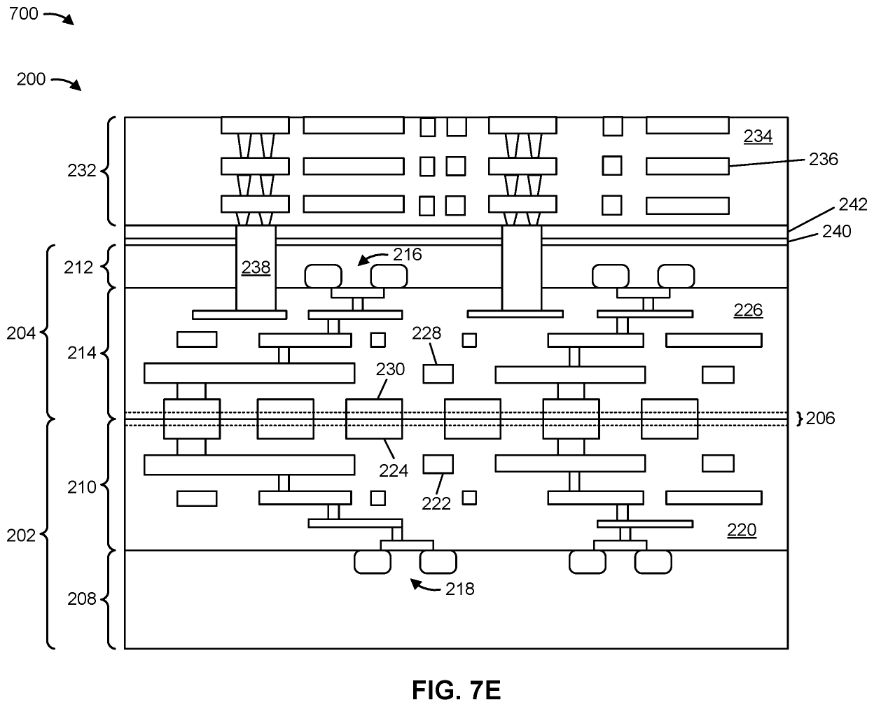

FIGS. 7A-7E are diagrams of an example implementation 700 of forming a portion of a semiconductor die package 200 described herein. In some implementations, one or more operations described in connection with FIGS. 7A-7E may be performed by one or more of the semiconductor processing tools 102-114 and/or the wafer/die transport tool 116. In some implementations, one or more operations described in connection with FIGS. 7A-7E may be performed by another semiconductor processing tool.

As shown in FIG. 7A, the semiconductor die 202 and the semiconductor die 204 may be bonded at the bonding interface 206 such that the semiconductor die 202 and the semiconductor die 204 are vertically arranged or stacked in a direct bonding configuration. The bonding tool 114 may perform a bonding operation to bond the semiconductor die 202 and the semiconductor die 204 at the bonding interface 206. The bonding operation may include a direct bonding operation in which bonding of semiconductor die 202 and the semiconductor die 204 is achieved through the physical connection of the contacts 224 with the contacts 230.

As shown in FIG. 7B, the buffer oxide layer 240 may be formed on the semiconductor die 204. The semiconductor die 204 may be bonded with the semiconductor die 202 at a first side of the semiconductor die 204, which may correspond to a first side of the interconnect region 214. The buffer oxide layer 240 may be formed on a second side of the semiconductor die 204 opposing the first side, which may correspond to a first side of the device region 212 of the semiconductor die 204. The deposition tool 102 may deposit the buffer oxide layer 240 using an epitaxy technique, a CVD technique, a PVD technique, an ALD technique, another deposition technique described above in connection with FIG. 1, and/or a deposition technique other than as described above in connection with FIG. 1.

As further shown in FIG. 7B, the high-k dielectric layer 242 may be formed over the semiconductor die 204. The high-k dielectric layer 242 may be formed over the second side of the semiconductor die 204 opposing the first side, which may correspond to the first side of the device region 212 of the semiconductor die 204. The high-k dielectric layer 242 may be formed on the buffer oxide layer 240. The deposition tool 102 may deposit the buffer oxide layer 240 using an epitaxy technique, a CVD technique, a PVD technique, an ALD technique, another deposition technique described above in connection with FIG. 1, and/or a deposition technique other than as described above in connection with FIG. 1. The high-k dielectric layer 242 may be deposited at a temperature that is included in a range of approximately 150 degrees Celsius to approximately 300 degrees Celsius. However, other values for the range are within the scope of the present disclosure.

As described above the high-k dielectric layer 242 may have an intrinsic negative polarity. Accordingly, forming the high-k dielectric layer 242 may include depositing one or more materials having an intrinsic negative charge polarity to form the high-k dielectric layer 242. The intrinsic negative charge polarity results from lattice defects, in the one or more materials, that form during deposition of the one or more materials.

As shown in FIG. 7C, one or more recesses 702 may be formed through the high-k dielectric layer 242, through the buffer oxide layer 240, through the silicon substrate of the device region 212, and into a portion of the dielectric layer 226 of the interconnect region 214. The one or more recesses 702 may be formed to expose one or more portions of a metallization layer 228 in the interconnection region 214. Thus, the one or more recesses 702 may be formed over the one or more portions of a metallization layer 228.

In some implementations, a pattern in a photoresist layer is used to form the one or more recesses 702. In these implementations, the deposition tool 102 forms the photoresist layer on the high-k dielectric layer 242. The exposure tool 104 exposes the photoresist layer to a radiation source to pattern the photoresist layer. The developer tool 106 develops and removes portions of the photoresist layer to expose the pattern. The etch tool 108 etches through the high-k dielectric layer 242, through the buffer oxide layer 240, through the device region 212, and into the interconnect region 214 to form the one or more recesses 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the one or more recesses 702 based on a pattern.

As shown in FIG. 7D, one or more BTSV structures 238 may be formed in the one or more recesses 702. In this way, the one or more BTSV structures 238 extend through the high-k dielectric layer 242, through the buffer oxide layer 240, through the device region 212, and into the interconnect region 214. Moreover, one or more BTSV structures 238 may be formed adjacent to one or more semiconductor devices 216 in the device region 212, and may be formed through one or more p-wells (e.g., p-wells that are associated with one or more semiconductor devices 216) in the silicon substrate of the device region 212. The one or more BTSV structures 238 may be electrically connected and/or physically connected with the one or more portions of the metallization layer 228 that were exposed through the one or more recesses 702.

The deposition tool 102 and/or the plating tool 112 may deposit the one or more BTSV structures 238 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the one or more BTSV structures 238 after the one or more BTSV structures 238 are deposited.

As shown in FIG. 7E, the top metal region 232 of the semiconductor die package 200 may be formed over the semiconductor die 204. One or more of the semiconductor processing tools 102-114 may form the top metal region 232 by forming one or more dielectric layers 234 and forming a plurality of metallization layers 236 in the plurality of dielectric layers 234. For example, the deposition tool 102 may deposit a first layer of the one or more dielectric layers 234 (e.g., using a CVD technique, an ALD technique, a PVD technique, and/or another type of deposition technique), the etch tool 108 may remove portions of the first layer to form recesses in the first layer, and the deposition tool 102 and/or the plating tool 112 may form a first metallization layer of the plurality of metallization layers 236 in the recesses (e.g., using a CVD technique, an ALD technique, a PVD technique, an electroplating technique, and/or another type of deposition technique). At least a portion of the first metallization layer may be electrically connected and/or physically connected with the one or more BTSV structures 238. The deposition tool 102, the etch tool 108, the plating tool 112, and/or another semiconductor processing tool may continue to perform similar processing operations to forming the top metal region 232 until a sufficient or desired arrangement of metallization layers 236 is achieved.

As indicated above, FIGS. 7A-7E are provided as an example. Other examples may differ from what is described with regard to FIGS. 7A-7E.

FIGS. 8A-8H are diagrams of an example implementation 800 of forming a portion of a semiconductor die package 200 described herein. In some implementations, one or more operations described in connection with FIGS. 8A-8H may be performed after one or more operations described in connection with FIGS. 7A-7E. In some implementations, one or more operations described in connection with FIGS. 8A-8H may be performed by one or more of the semiconductor processing tools 102-114 and/or the wafer/die transport tool 116. In some implementations, one or more operations described in connection with FIGS. 8A-8H may be performed by another semiconductor processing tool.

As shown in FIG. 8A, one or more dielectric layers may be formed over the semiconductor die 202 and over the semiconductor die 204 that is bonded with the semiconductor die 202. For example, a dielectric layer 246a may be formed over and/or on the top metal region 232 that is over the semiconductor dies 202 and 204. As another example, a dielectric layer 248a may be formed over and/or on the dielectric layer 246a. As another example, a dielectric layer 246b may be formed over and/or on the dielectric layer 248a. As another example, a dielectric layer 250a may be formed over and/or on the dielectric layer 246b. As another example, a dielectric layer 248b may be formed over and/or on the dielectric layer 250a. The deposition tool 102 may deposit the dielectric layers 246a, 246b, 248a, 248b, and/or 250a using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the dielectric layers 246a, 246b, 248a, 248b, and/or 250a after the dielectric layers 246a, 246b, 248a, 248b, and/or 250a are deposited.

As shown in FIG. 8B, one or more recesses 802 may be formed through at least a subset of the dielectric layers 246a, 246b, 248a, 248b, and/or 250a. For example, the one or more recesses 802 may be formed through the dielectric layers 246b, 248b, and 250a. The one or more recesses 802 may extend into a portion of the dielectric layer 248a such that another portion of the dielectric layer 248a remains over the top metal region 232, and between the one or more recesses 802 and the top metal region 232. Moreover, the dielectric layer 246a may remain over the top metal region 232, and between the one or more recesses 802 and the top metal region 232.

In some implementations, a pattern in a photoresist layer is used to form the one or more recesses 802. In these implementations, the deposition tool 102 forms the photoresist layer on the dielectric layer 248b. The exposure tool 104 exposes the photoresist layer to a radiation source to pattern the photoresist layer. The developer tool 106 develops and removes portions of the photoresist layer to expose the pattern. The etch tool 108 etches through the dielectric layers 246b, 248b, and 250a, and into the dielectric layer 248a, to form the one or more recesses 802. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the one or more recesses 802 based on a pattern.

As shown in FIG. 8C, one or more dielectric layers may be formed over and/or on the dielectric layers 246a, 246b, 248a, 248b, and/or 250a. For example, a dielectric layer 250b may be formed over and/or on the dielectric layer 248b. As another example, a dielectric layer 804 may be formed over and/or on the dielectric layer 250b. As another example, a dielectric layer 806 may be formed over and/or on the dielectric layer 804. The dielectric layer 250b may include silicon oxynitride (SiON) and/or another suitable dielectric material. The dielectric layer 804 may include a silicon oxide (SiOₓ such as SiO₂) and/or another suitable dielectric material. The dielectric layer 806 may include a silicon nitride (SiₓN_{y} such as Si₃N₄) and/or another suitable dielectric material.

The deposition tool 102 may deposit the dielectric layers 250b, 804, and/or 806 using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the dielectric layers 250b, 804, and/or 806 after the dielectric layers 250b, 804, and/or 806 are deposited. As shown in FIG. 8C, the dielectric layers 250b, 804, and/or 806 may partially fill in the one or more recesses 802.

As shown in FIG. 8D, the dielectric layers 246a, 246b, 248a, 248b, 250a, 250b, 804, and 806 may be etched in one or more etch operations to expand the recesses 802. The one or more etch operations may result in formation of one or more dual damascene recesses 808 that extend through the dielectric layers 246a, 246b, 248a, 248b, 250a, 250b, 804, and 806 to the top metal region 232. One or more metallization layers 236 of the top metal region 232 may be exposed through the one or more dual damascene recesses 808.

In some implementations, a pattern in a photoresist layer is used to form the one or more dual damascene recesses 808. In these implementations, the deposition tool 102 forms the photoresist layer on the dielectric layer 806. The exposure tool 104 exposes the photoresist layer to a radiation source to pattern the photoresist layer. The developer tool 106 develops and removes portions of the photoresist layer to expose the pattern. The etch tool 108 etches through the dielectric layers 246a, 246b, 248a, 248b, 250a, 250b, 804, and 806 to form the one or more dual damascene recesses 808. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the one or more dual damascene recesses 808 based on a pattern.

As shown in FIG. 8E, one or more conductive terminals 244 may be formed in the one or more dual damascene recesses 808. The conductive terminals 244 may include copper (Cu) pads or another type of conductive structures. The deposition tool 102 and/or the plating tool 112 may deposit the conductive terminals 244 using a CVD technique, a PVD technique, an ALD technique, an electroplating technique, another deposition technique described above in connection with FIG. 1, and/or a deposition technique other than as described above in connection with FIG. 1. In particular, the deposition tool 102 and/or the plating tool 112 may deposit the conductive terminals 244 at a relatively low temperature to reduce the likelihood of thermal deformation and warpage of the semiconductor dies 202 and/or 204 of the semiconductor die package 200.

In some implementations, the plating tool 112 uses an electroplating deposition technique to deposit the conductive terminals 244. In these implementations, the conductive material (e.g., copper (Cu) or another suitable conductive material) is deposited at a temperature that is below approximately 150 degrees Celsius using the electroplating deposition technique. For example, the conductive material may be deposited at approximately room temperature using the electroplating deposition technique. The electroplating deposition technique may include applying a voltage across an anode formed of a plating material and a cathode (e.g., the semiconductor die package 200). The voltage causes a current to oxidize the anode, which causes the release of plating material ions from the anode. These plating material ions form a plating solution that travels through a plating bath toward the semiconductor die package 200. The plating solution reaches the substrate and deposits plating material ions into the dual damascene recesses 808 to form the conductive terminals 244 of the semiconductor die package 200.

In some implementations, a seed layer 810 may be deposited in the dual damascene recesses 808 prior to the electroplating operation. The seed layer 810 may include a copper seed layer that is formed by CVD, PVD, ALD, and/or another deposition technique used by the deposition tool 102. The seed layer 810 may be formed on the inner walls of the damascene recesses 808. The seed layer 810 may be formed on the inner walls of the damascene recesses 808 to promote and/or facilitate adhesion of the conductive terminals 244 to the inner walls of the damascene recesses 808. Moreover, one or more barrier layers 254 may be formed on the inner walls of the damascene recesses 808 prior to formation of the seed layer 810, and the seed layer 810 promotes and/or facilitates adhesion of the conductive terminals 244 to the barrier layers 254.

As shown in FIG. 8F, the planarization tool 110 may perform a CMP operation to planarize the one or more conductive terminals 244 after the conductive material is deposited to form the one or more conductive terminals 244. The CMP operation results in removal of the dielectric layers 804 and 806 from the semiconductor die package 200. Moreover, the CMP operation results in the top surface of the one or more conductive terminals 244 being co-planar with the top surface of the dielectric layer 250b.

As shown in FIG. 8G, one or more dielectric layers may be formed over and/or on the one or more conductive terminals 244. For example, a dielectric layer 246c may be formed over and/or on the one or more conductive terminals 244 (as well as over and/or on the dielectric layer 250b). As another example, a dielectric layer 248c may be formed over and/or on the dielectric layer 246c. As another example, a dielectric layer 246d may be formed over and/or on the dielectric layer 248c. The dielectric layers 246c and 246d may each include a silicon nitride (SiₓN_{y} such as Si₃N₄) and/or another suitable dielectric material. The dielectric layer 248c may include a silicon oxide (SiOₓ such as SiO₂) and/or another suitable dielectric material.

The deposition tool 102 may deposit the dielectric layers 246c, 246d, and/or 248c using an epitaxy technique, a CVD technique, a PVD technique, an ALD technique, another deposition technique described above in connection with FIG. 1, and/or a deposition technique other than as described above in connection with FIG. 1. In some implementations, the planarization tool 110 may perform a CMP operation to planarize the dielectric layers 246c, 246d, and/or 248c after the dielectric layers 246c, 246d, and/or 248c are deposited.

As further shown in FIG. 8G, in some implementations, a polymer layer 252 may be formed over and/or on the dielectric layer 246d. The deposition tool 102 may deposit the polymer layer 252 using an epitaxy technique, a CVD technique, a PVD technique, an ALD technique, another deposition technique described above in connection with FIG. 1, and/or a deposition technique other than as described above in connection with FIG. 1. Alternatively, the polymer layer 252 may be omitted from the semiconductor die package 200.

As shown in FIG. 8H, the dielectric layers 246c, 246d, and 248c may be etched to form one or more recesses 812 in the dielectric layers 246c, 246d, and 248c. The one or more recesses 812 may be formed such that the top surfaces of the one or more conductive terminals 244 are exposed through the one or more recesses 812. In some implementations, the polymer layer 252 is also etched to form the one or more recesses 812 through the polymer layer 252.

In some implementations, a pattern in a photoresist layer is used to form the one or more recesses 812. In these implementations, the deposition tool 102 forms the photoresist layer on the dielectric layer 246d (or on the polymer layer 252 in implementations in which the polymer layer 252 is included). The exposure tool 104 exposes the photoresist layer to a radiation source to pattern the photoresist layer. The developer tool 106 develops and removes portions of the photoresist layer to expose the pattern. The etch tool 108 etches through the dielectric layers 246c, 246d, and 248c (and through the polymer layer 252 in implementations in which the polymer layer 252 is included) to form the one or more recesses 812. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the one or more recesses 812 based on a pattern.

As further shown in FIG. 8H, in some implementations, a recess 812 may include different widths along the profile of the recess 812. For example, the recess 812 may include a width (W4) through the dielectric layers 246c, 246d, and 248c, and a width (W5) through the polymer layer 252. The width (W5) of the recess 812 through the polymer layer 252 may be greater relative to the width (W4) of the recess 812 through the dielectric layers 246c, 246d, and 248c.

As indicated above, FIGS. 8A-8H are provided as an example. Other examples may differ from what is described with regard to FIGS. 8A-8H.

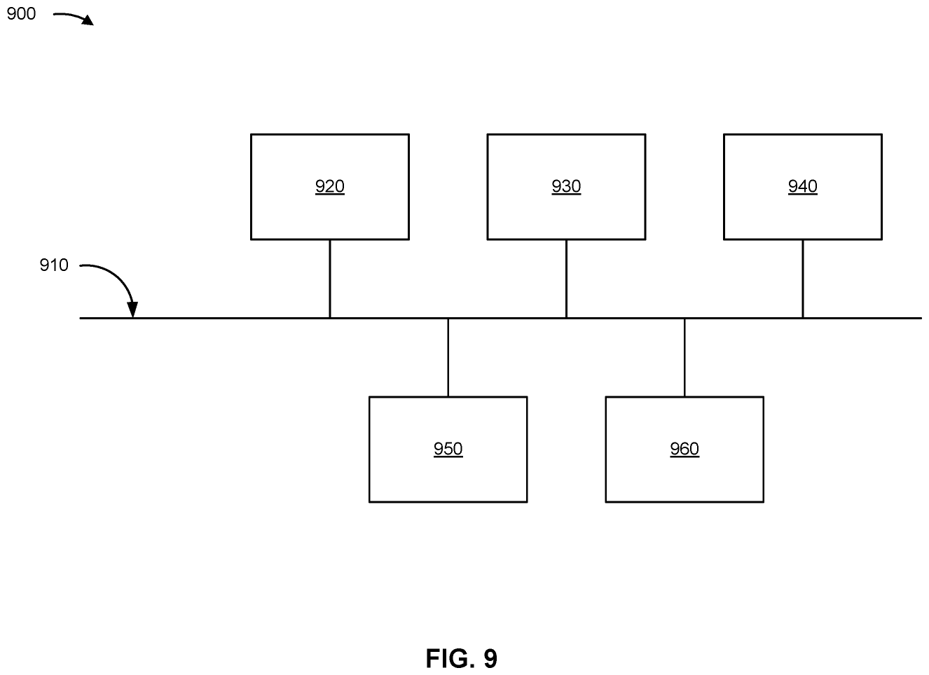

FIG. 9 is a diagram of example components of a device 900 described herein. In some implementations, one or more of the semiconductor processing tools 102-114 and/or the wafer/die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

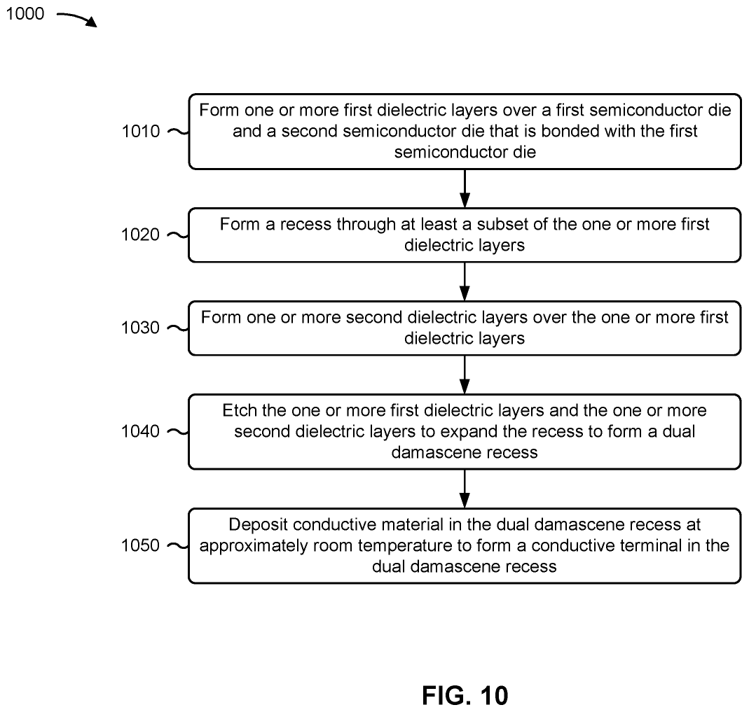

FIG. 10 is a flowchart of an example process 1000 associated with forming a semiconductor die package. In some implementations, one or more process blocks of FIG. 10 are performed by one or more semiconductor processing tools (e.g., one or more of the semiconductor processing tools 102-114). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming one or more first dielectric layers over a first semiconductor die and a second semiconductor die that is bonded with the first semiconductor die (block 1010). For example, one or more of the semiconductor processing tools 102-114 may form one or more first dielectric layers (e.g., one or more of the dielectric layers 246a, 246b, 248a, 248b, 250a) over a first semiconductor die 202 and a second semiconductor die 204 that is bonded with the first semiconductor die 202, as described herein.

As further shown in FIG. 10, process 1000 may include forming a recess through at least a subset of the one or more first dielectric layers (block 1020). For example, one or more of the semiconductor processing tools 102-114 may form a recess 802 through at least a subset of the one or more first dielectric layers, as described herein.

As further shown in FIG. 10, process 1000 may include forming one or more second dielectric layers over the one or more first dielectric layers (block 1030). For example, one or more of the semiconductor processing tools 102-114 may form one or more second dielectric layers (e.g., one or more of the dielectric layers 250b, 804, 806) over the one or more first dielectric layers, as described herein.

As further shown in FIG. 10, process 1000 may include etching the one or more first dielectric layers and the one or more second dielectric layers to expand the recess to form a dual damascene recess (block 1040). For example, one or more of the semiconductor processing tools 102-114 may etch the one or more first dielectric layers and the one or more second dielectric layers to expand the recess 802 to form a dual damascene recess 808, as described herein.

As further shown in FIG. 10, process 1000 may include depositing conductive material in the dual damascene recess at approximately room temperature to form a conductive terminal in the dual damascene recess (block 1050). For example, one or more of the semiconductor processing tools 102-114 may deposit conductive material in the dual damascene recess 808 at approximately room temperature to form a conductive terminal 244 in the dual damascene recess 808, as described herein.

Process 1000 may include additional implementations, such as any single implementation or any combination of implementations described below and/or in connection with one or more other processes described elsewhere herein.

In a first implementation, depositing the conductive material in the dual damascene recess 808 includes depositing the conductive material in the dual damascene recess using an electroplating deposition technique.

In a second implementation, alone or in combination with the first implementation, process 1000 includes planarizing the conductive terminal 244 after depositing the conductive material to form the conductive terminal 244, where planarizing the conductive terminal 244 results in removal of at least a subset of the one or more second dielectric layers.

In a third implementation, alone or in combination with one or more of the first and second implementations, process 1000 includes forming one or more third dielectric layers (e.g., one or more of the dielectric layers 246c, 246d, 248c) over the conductive terminal 244 after planarizing the conductive terminal 244.

In a fourth implementation, alone or in combination with one or more of the first through third implementations, process 1000 includes etching the one or more third dielectric layers to form a recess 812 in the one or more third dielectric layers, where a top surface of the conductive terminal 244 is exposed through the recess 812.

In a fifth implementation, alone or in combination with one or more of the first through fourth implementations, the conductive material includes copper (Cu).

In a sixth implementation, alone or in combination with one or more of the first through fifth implementations, depositing the conductive material in the dual damascene recess 808 includes depositing the conductive material in the dual damascene recess 808 after bonding the first semiconductor die 202 with the second semiconductor die 204.

In a seventh implementation, alone or in combination with one or more of the first through sixth implementations, forming the recess 802 includes forming the recess 802 through at least the subset of the one or more first dielectric layers such that portions of the one or more first dielectric layers remain over a top metal region 232 that is above the second semiconductor die 204.

In an eighth implementation, alone or in combination with one or more of the first through seventh implementations, etching the one or more first dielectric layers and the one or more second dielectric layers to expand the recess 802 to form the dual damascene recess 808 includes etching through the one or more first dielectric layers and through the one or more second dielectric layers such that a portion of the top metal region 232 is exposed through the dual damascene recess 808.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, semiconductor dies of a semiconductor die package are directly bonded, and a top metal region may be formed over the semiconductor dies. A plurality of conductive terminals may be formed over the top metal region. The conductive terminals are formed of copper (Cu) or another material that enables low-temperature deposition process techniques, such as electroplating, to be used to form the conductive terminal. In this way, the conductive terminals of the semiconductor die packages described herein may be formed at a relatively low temperature, such as below approximately 150 degrees Celsius and/or at or near room temperature. This reduces the likelihood of thermal deformation of semiconductor dies in the semiconductor die packages. The reduced thermal deformation reduces the likelihood of warpage, breakage, and/or other types of damage to the semiconductor dies of the semiconductor die packages, which may increase performance and/or increase yield of semiconductor die packages.

As described in greater detail above, some implementations described herein provide a semiconductor structure. The semiconductor structure includes a first semiconductor die. The semiconductor structure includes a second semiconductor die bonded with the first semiconductor die such that the first semiconductor die and the second semiconductor die are vertically arranged in the semiconductor structure. The semiconductor structure includes a top metal region over the second semiconductor die. The semiconductor structure includes one or more dielectric layers over the top metal region. The semiconductor structure includes one or more copper (Cu) pads included in the one or more dielectric layers.

As described in greater detail above, some implementations described herein provide a method. The method includes forming one or more first dielectric layers over a first semiconductor die and a second semiconductor die that is bonded with the first semiconductor die. The method includes forming a recess through at least a subset of the one or more first dielectric layers. The method includes forming one or more second dielectric layers over the one or more first dielectric layers. The method includes etching the one or more first dielectric layers and the one or more second dielectric layers to expand the recess to form a dual damascene recess. The method includes depositing conductive material in the dual damascene recess at approximately room temperature to form a conductive terminal in the dual damascene recess.

As described in greater detail above, some implementations described herein provide a semiconductor structure. The semiconductor structure includes a first semiconductor die comprising a first set of contacts; a second semiconductor die comprising a second set of contacts, where the first semiconductor die and the second semiconductor die are bonded at the first set of contacts and the second set of contacts such that the first semiconductor die and the second semiconductor die are vertically arranged in the semiconductor structure; a top metal region over the second semiconductor die and on an opposing side of the second semiconductor die as the second set of contacts; and a plurality of dielectric layers over the top metal region; one or more copper (Cu) pads included in a first subset of the one or more dielectric layers, where a second subset of the plurality of dielectric layers are above top surfaces of the one or more copper pads such that the one or more copper pads are exposed through the second subset of the one or more dielectric layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor die;
a second semiconductor die bonded with the first semiconductor die such that the first semiconductor die and the second semiconductor die are vertically arranged in the semiconductor structure;
a top metal region over the second semiconductor die;
one or more dielectric layers over the top metal region; and
one or more copper (Cu) pads formed in the one or more dielectric layers.

2. The semiconductor structure of claim 1, wherein the one or more dielectric layers extend above top surfaces of the one or more copper pads such that the one or more copper pads are included in one or more recesses in the one or more dielectric layers; and
wherein the semiconductor structure comprises a barrier layer between the one or more copper pads and the one or more dielectric layers.

3. The semiconductor structure of claim 1, wherein a copper pad, of the one or more copper pads, comprises:
a tapered portion; and
an approximately straight-walled portion over the tapered portion; and
wherein the copper pad includes at least 50% copper.

4. The semiconductor structure of claim 3, wherein a height of the approximately straight-walled portion is greater relative to a height of the tapered portion.

5. The semiconductor structure of claim 3, wherein a ratio, of a height of the approximately straight-walled portion to a height of the tapered portion, is included in a range of approximately 1.8:1 to approximately 18:1.

6. The semiconductor structure of claim 3, wherein a ratio, of a height of the tapered portion to a width of a top of the tapered portion, is included in a range of approximately 0.25:1 to approximately 2.7:1.

7. The semiconductor structure of claim 3, wherein a ratio, of a width of the approximately straight-walled portion to a height of the approximately straight-walled portion, is included in a range of approximately 3.8:1 to approximately 35.7:1.

8. A method, comprising:
forming one or more first dielectric layers over a first semiconductor die and a second semiconductor die that is bonded with the first semiconductor die;
forming a recess through at least a subset of the one or more first dielectric layers;
forming one or more second dielectric layers over the one or more first dielectric layers;
etching the one or more first dielectric layers and the one or more second dielectric layers to expand the recess to form a dual damascene recess; and
depositing conductive material in the dual damascene recess at approximately room temperature to form a conductive terminal in the dual damascene recess.

9. The method of claim 8, wherein depositing the conductive material in the dual damascene recess comprises:
depositing the conductive material in the dual damascene recess using an electroplating deposition technique.

10. The method of claim 8, further comprising:
planarizing the conductive terminal after depositing the conductive material to form the conductive terminal,
wherein planarizing the conductive terminal results in removal of at least a subset of the one or more second dielectric layers.

11. The method of claim 10, further comprising:
forming one or more third dielectric layers over the conductive terminal after planarizing the conductive terminal.

12. The method of claim 11, further comprising:
etching the one or more third dielectric layers to form a recess in the one or more third dielectric layers,
wherein a top surface of the conductive terminal is exposed through the recess.

13. The method of claim 8, wherein the conductive material comprises copper (Cu).

14. The method of claim 8, wherein depositing the conductive material in the dual damascene recess comprises:
depositing the conductive material in the dual damascene recess after bonding the first semiconductor die with the second semiconductor die.

15. The method of claim 8, wherein forming the recess comprises:
forming the recess through at least the subset of the one or more first dielectric layers such that portions of the one or more first dielectric layers remain over a top metal region that is above the second semiconductor die.

16. The method of claim 15, wherein etching the one or more first dielectric layers and the one or more second dielectric layers to expand the recess to form the dual damascene recess comprises:
etching through the one or more first dielectric layers and through the one or more second dielectric layers such that a portion of the top metal region is exposed through the dual damascene recess.

17. A semiconductor structure, comprising:
a first semiconductor die comprising a first set of contacts;
a second semiconductor die comprising a second set of contacts,
wherein the first semiconductor die and the second semiconductor die are bonded at the first set of contacts and the second set of contacts such that the first semiconductor die and the second semiconductor die are vertically arranged in the semiconductor structure;
a top metal region over the second semiconductor die and on an opposing side of the second semiconductor die as the second set of contacts;
a plurality of dielectric layers over the top metal region; and
one or more copper (Cu) pads included in a first subset of the one or more dielectric layers,
wherein a second subset of the plurality of dielectric layers are above top surfaces of the one or more copper pads such that the one or more copper pads are exposed through the second subset of the one or more dielectric layers.

18. The semiconductor structure of claim 17, wherein a copper pad, of the one or more copper pads, comprises:
a first portion having tapered sidewalls; and
a second portion, over the first portion, having approximately parallel sidewalls,
wherein a width of the second portion is greater relative to a width of the first portion.

19. The semiconductor structure of claim 18, wherein a height of the first portion is greater relative to a width of a bottom surface of the first portion; and
wherein a width of a top of the first portion is greater relative to the width of the bottom surface of the first portion.

20. The semiconductor structure of claim 17, wherein a top surface of a copper pad, of the one or more copper pads, is exposed through a recess in the second subset of the plurality of dielectric layers and in a polymer layer over the plurality of dielectric layers;
wherein a first width of the recess through the polymer layer is greater relative to a second width of the recess through the second subset of the plurality of dielectric layers.
